(19) United States
(12) Patent Application Publication
(10) Pub. No.: US 2009/0021873 A1
(43) Pub. Date: Jan. 22, 2009

(54) ELECTRO STATIC DISCHARGE PROTECTION IN INTEGRATED CIRCUITS

(75) Inventors: Matthias Spode, Halstenbek (DE); Hans Martin Ritter, Nahe (DE); Ruediger Leuner, Hamburg (DE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/278,675

(22) PCT Filed: Feb. 13, 2007
(86) PCT No.: PCT/IB2007/050465

§ 371 Date: Aug. 7, 2008

(30) Foreign Application Priority Data
Feb. 17, 2006 (EP) 06110085.5

(51) Int. Cl. H02H 9/04; H01L 23/58; H01L 21/76

(52) U.S. Cl. 361/56; 257/491; 438/435; 257/E29.008; 257/E21.54

(57) ABSTRACT

It is described an Electro Static Discharge protection, wherein diodes are arranged on two electric paths both extending in between two conductors which are connected with input terminals of an ESD sensitive electronic component. Each path comprises two diodes arranged in series and with opposite polarity with respect to each other. At least one of the totally four diodes comprises a different reverse breakdown voltage. The protection circuit is formed integrally with the ESD sensitive electronic component. Due to the serial connection of two diodes in each path the corresponding ESD protection circuit comprises an extremely low capacitance.

### FIELD OF THE INVENTION

The present invention relates to the field of overvoltage and current protection of electronic devices. More particular the present invention relates to the field of protecting sensitive electronic components from being damaged due to Electro Static Discharge currents.

### BACKGROUND OF THE INVENTION

In order to protect many electronic devices like mobile phones, USB-sticks etc from being damaged due to unwanted electrostatic discharge (ESD) currents, the inputs of such devices are commonly furnished with ESD-protection devices. As space in modern complementary metal oxide semiconductor (CMOS) processes is very expensive and the CMOS components are very sensitive to overvoltages, mostly discrete solutions or integrated discretes are used in order to protect CMOS devices from being damaged. A discrete solution is defined by an ESD protection circuit, which is built up separately from the electronic device, which is supposed to be protected. An integrated discrete is an integrated ESD protection circuit which is also separated from the protected integrated electronic device. Integrated discretes have the advantage that they allow to save a lot of space and money as compared to discrete solutions.

From the application side there are two main requirements for ESD protection circuits. First they should provide a reliable ESD-protection and second they should keep capacitance low enough in order to enable high frequency input signals.

For signals with both positive and negative voltages two diodes arranged with respect to each other in a so-called back-to-back configuration are widely used for ESD protection. Thereby, the two diodes are arranged in series between two terminals of the device, which is supposed to be ESD protected.

US 2003/0116779 A1 discloses a low-capacitance bidirectional device for protection against overvoltages, which device is suitable to be used at high frequencies. The protection device is provided as an above described integrated discrete. The protection device includes first and second discrete one-way Shockley diodes, the cathode and the anode of the first diode being respectively connected to the anode and to the cathode of the second diode. The reverse breakdown voltage of each diode ranges between 50V and 125V.

### OBJECT AND SUMMARY OF THE INVENTION

There may be a need for an effective and a reliable Electro Static Discharge protection, which may be provided within a compact configuration.

This need may be met by a circuit arrangement for protecting electronic components from being damaged due to voltage overloads, in particular for protecting semiconductor devices from being damaged due to unwanted electrostatic discharge currents as set forth in claim 1. According to a first aspect of the invention the circuit arrangement comprises a first conductor, adapted to be connected to a first voltage level, a second conductor, adapted the be connected to a second voltage level, a first electric path interconnecting the first conductor and the second conductor and a second electric path interconnecting the first conductor and the second conductor. The circuit arrangement further comprises a first diode and a second diode arranged within the first electric path in series and with opposite polarity with respect to each other, wherein the first diode has a first reverse breakdown voltage and the second diode has a second reverse breakdown voltage. Further, there is provided a third diode and a fourth diode arranged within the second electric path in series and with opposite polarity with respect to each other, wherein the third diode has a third reverse breakdown voltage and the fourth diode has a fourth reverse breakdown voltage which is different from the third reverse breakdown voltage. The circuit arrangement is formed integrally with at least one further electronic component, which is connected to the first conductor and to the second conductor, respectively.

The described circuit arrangement provides the advantage, that two diodes are combined in series within one electric path such that the resultant capacitance of the two diodes is always smaller than the capacitance of the single diode having the smaller capacitance. The resultant capacitance is reduced in particular because of the fact that two diodes comprising different breakdown voltages are connected within the second electric path. In this context one has to consider that a diode with a high breakdown voltage usually has a smaller capacitance than a diode with a lower breakdown voltage. Therefore, the resultant capacitance of the whole circuit arrangement is reduced. As a consequence, the described circuit arrangement is suitable also for applications wherein high frequency signals, in particular high frequency data signals are applied to the two conductors.

The described aspect of the invention is based on the idea that the diodes may be combined in such a way, that depending on the polarity or the direction of the ESD voltage peak the current will flow predominantly through one of the two paths.

The first diode and the second diode are arranged within the first electric path in series and with opposite polarity. The same holds for the third and the fourth diode, which are arranged within the second electric path also in series and with opposite polarity. This means, that either the anodes or the cathodes of the diodes arranged within one electric path are conductively connected.

According to this aspect of the invention all electronic components are formed integrally. Therefore, an ESD protected electronic device may be built up reasonable priced in a compact design.

According to an embodiment of the invention as set forth in claim 2, the circuit arrangement and the further electronic component are formed within one semiconductor crystal. This may provide the advantage that ESD protected electronic devices may be formed by means of one single semiconductor manufacturing process.

According to a further embodiment of the invention as set forth in claim 3, the second voltage level is at ground level (GND). Since a conductor for ground electric voltage is available usually in every electric circuit the circuit arrangement may allow both an easy and an effective ESD protection for one or for more than one electronic component.

According to a further embodiment of the invention as set forth in claim 4, the first diode and the third diode are arranged in the same polarity with respect to the first conductor and the second diode and the fourth diode are arranged in the same polarity with respect to the second conductor, respectively. Such a symmetric design has the advantage that the ESD protection circuit arrangement may provide an in particular reliable ESD protection. Further, the protection circuit may be produced by means of standard semiconductor manufacturing processes.

According to a further embodiment of the invention as set forth in claim 5, the first reverse breakdown voltage is the same as the fourth reverse breakdown voltage and the second reverse breakdown voltage is the same as the third reverse breakdown voltage. In this configuration two diodes of low capacitance and high breakdown voltage are combined with two diodes with low breakdown voltage and high capacitance. The various diodes are combined in such a way that, depending on the direction of an ESD-current, only one electric path out of the two paths will conduct the whole current. The path conducting the current comprises a forward biased low capacitance diode in series with a high capacitance diode biased in reverse breakdown.

The described symmetric solution may be realized in standard bipolar semiconductor manufacturing process. Thereby, emitter-base diodes and collector-base diodes, which are automatically created when a transistor is built up, may be used as the first, second, third and/or fourth diode.

According to a further embodiment of the invention as set forth in claim 6, the first reverse breakdown voltage is between 30V and 100V, preferably between 50V and 80V, and the second reverse breakdown voltage is between 3V and 20V, preferably between 5V and 15V. By using diodes with these reverse breakdown voltages a reliably ESD protection for a variety of different electronic devices may be guaranteed. Such electronic devices may be for instance sensitive components used for USB-sticks, mobile phones and/or other apparatuses, which are used in modem consumer electronic and/or information technology.

According to a further embodiment of the invention as set forth in claim 7, the first, the second and the third reverse breakdown voltages have the same value. Such a non-symmetric design has the advantage that the ESD protection circuit arrangement may be built up by employing a very simple and effective semiconductor manufacturing process. In principle only of four mask processes are needed in order to build up this asymmetric protection circuit.

Therefore, the feature of an ESD protection may be implemented in many different electronic devices without increasing the costs of the ESD protected devices significantly. This provides the advantage that reliable electronic devices may be built up at reasonable manufacturing costs.

According to a further embodiment of the invention as set forth in claim 8, the circuit arrangement further comprises a first resistor arranged in the first electric path and a second resistor arranged in the second electric path. The resistors provide the advantage that in case of an overvoltage peak with a predefined polarity the current distribution between the two electric paths can be adjusted properly such that an optimal ESD protection might be guaranteed.

According to a further embodiment of the invention as set forth in claim 9, the first resistor is arranged in series with respect to the first diode and with respect to the second diode, respectively. In a corresponding manner also the second resistor is arranged in series with respect to the third diode and with respect to the fourth diode, respectively. Such a resistor-containing configuration of the protection circuit has the advantage that a very precise adjustment for directing the overall ESD-current onto the two electric paths may be carried out because when selecting the ohmic values of the two resistors the internal resistors of the diodes may be taken into account. Thereby, a very precise current distribution between the two electric paths may be achieved.

According to a further embodiment of the invention as set forth in claim 10, the first reverse breakdown voltage is between 3V and 20V, preferably between 5V and 15V, and the fourth reverse breakdown voltage is between 30V and 100V, preferably between 50V and 80V. In case of the asymmetric ESD protection described with this embodiment of the invention diodes with reverse breakdown voltages in the given voltage ranges provide an in particular reliable ESD protection.

The above-mentioned need may further be met by an integrated electronic device as set forth in claim 11. According to this aspect of the invention the integrated electronic device comprises an electronic component, which is supposed to be protected, and a circuit arrangement according to any embodiment described above.

This aspect of the invention is based on the idea that the production of an integrated protection circuit may be included in the manufacturing process of integrated circuits. As a benefit, there is provided the advantageously possibility to manufacture new types of ESD protected integrated circuit components which are much less sensitive to ESD voltage peaks and/or ESD currents compared to known integrated circuits. Therefore, reasonable priced and compact designed electronic apparatuses may be produced which are by far much more reliable than known apparatuses.

This above-mentioned need may further be met by an integrated circuit element for protecting electronic components from being damaged due to voltage overloads, in particular for protecting integrated semiconductor devices from being damaged due to unwanted electrostatic discharge currents, as set forth in claim 12.

According to this aspect of the invention the integrated circuit element comprises a first enriched semiconductor layer, a first enriched well structure and a second enriched well structure formed in the first enriched semiconductor layer, a first enriched region and a second enriched region, which are both formed in the first enriched well structure, a third enriched region formed in the second enriched well structure and a fourth enriched region formed in the first enriched semiconductor layer. The integrated circuit element further comprises a first passivation layer formed on a common surface defined by top surfaces portions of the first enriched semiconductor layer, by the first and second enriched well structures and by the first, the second, the third and the fourth enriched regions. The first passivation layer comprises four through holes for contacting the enriched regions. Further, the integrated circuit comprises a first contact element accommodated in a first through hole for contacting the first enriched region, a second contact element accommodated in a second through hole for contacting the second enriched region, a third contact element accommodated in a third through hole for contacting the third enriched region and a fourth contact element accommodated in a fourth through hole for contacting the fourth enriched region.

This aspect of the invention is based on the idea that a protection circuit arrangement as described above may be built up as an integrated circuit by means of a rather simple and effective semiconductor manufacturing process, which leads to the semiconductor topography as described.

Preferably, the contact elements are formed out of a metallic material like aluminum or copper.

According to an embodiment of the invention as set forth in claim 13, the integrated circuit element further comprises a substrate providing a basis for the first enriched semiconductor layer. Therefore, the circuit element may be built up by employing well-known techniques for forming and structuring layers of different materials onto a predefined substrate.

According to a further embodiment of the invention as set forth in claim 14, the substrate is a low ohmic enriched semiconductor material. A low ohmic substrate may have the advantage that a plurality of integrated circuit elements can be built up with a constant and high quality. A low ohmic substrate may further provide the advantage that there is only a small voltage drop generated by the substrate. In other words, the resistance, which is connected in series with the third diode and the fourth diode may be reduced.

According to a further embodiment of the invention as set forth in claim 15, the integrated circuit element further comprises a second passivation layer formed on the contact elements and on portions of the first passivation layer. This has the advantage that the whole integrated circuit element may be protected against mechanical and/or chemical damages.

According to a further embodiment of the invention as set forth in claim 16, the second passivation layer comprises openings for electrically connecting the contact elements. The contact elements of the integrated circuit element itself are preferably contacted by means of solder balls, which are formed in the region on and in the openings. Thereby, the integrated circuit element can be contacted with predefined contact pads or lands formed on a substrate (e.g. a printed circuit board) or on contact pads formed on other semiconductor devices. A permanent contact between the contact pads and the integrated circuit element is usually established with a solder or a gluing process.

However, as an alternative to the above described bumping the contacting may also be established with so-called bonding procedures, wherein a thin wire is permanently fixed to the contact elements.

According to a further embodiment of the invention as set forth in claim 17, the first enriched region is formed around the second enriched region in an arc wise manner, preferably in a circular arc wise manner. Thereby, the interface between the first enriched region and the first enriched well structure may represent a first diode whereas the interface between the second enriched region and the first enriched well structure may represent a second diode. It has been found out that in particular an almost concentric arrangement between the first enriched region and the second enriched region has the advantage that two diodes may be created which comprise a minimal internal resistance only.

The above-mentioned need may further be met by a method for manufacturing an integrated circuit element for protecting electronic components from being damaged due to voltage overloads, in particular for protecting integrated semiconductor devices from being damaged due to electrostatic discharge currents, as set forth in claim 18.

According to this aspect of the invention the method comprises the steps of (a) forming a first enriched semiconductor layer on a substrate, (b) forming a first enriched well structure and a second enriched well structure in the first layer. The method further comprises the steps of (c) forming a first enriched region and a second enriched region in the first well structure, (d) forming a third enriched region in the second enriched well structure, (e) forming a fourth enriched region in the first enriched semiconductor layer and (f) forming a first passivation layer on a surface defined by top surface portions of the first enriched semiconductor layer, the first and second enriched well structures and the first, the second, the third and the fourth enriched regions. Further, the described method comprises the steps of (g) forming four through holes in the first passivation layer and (h) forming four contact elements each being accommodated within one through hole such that each of the four enriched regions is contacted with one of the four contact elements.

This aspect of the invention is based on the idea that a protection circuit arrangement as described above may be built up as an integrated circuit by means of a rather simple and effective semiconductor manufacturing process.

According to an embodiment of the invention as set forth in claim 19, the method further comprises the step of forming a second passivation layer on the contact elements and on portions of the first passivation layer. This provides the advantage that the whole integrated circuit element may be protected against mechanical and/or chemical damages. The second passivation is preferably made of a Si₃N₄.

According to a further embodiment of the invention as set forth in claim 20, the method further comprises the steps of forming openings in the second passivation layer and electrically connecting the contact elements via these openings. The described steps are usually followed by a forthcoming step of electrically connecting the contacts elements. Such a step is typically carried out by forming solder balls in the regions on the openings and within the openings. As has already been mentioned above, the integrated circuit element can be contacted with predefined contact pads formed on a substrate.

However, as an alternative to the above described bumping the contacting may also be established with so-called bonding procedures, wherein a thin wire is permanently fixed to the electrical contacts.

According to a further embodiment of the invention as set forth in claim 21, the first enriched semiconductor layer is formed on the substrate by means of an epitaxial growth procedure. This may provide the advantage that the quality of the resulting semiconductor crystal is very high such that a plurality of integrated circuit elements may be manufactured with a constant narrow specification of electronic properties and/or electronic behaviors.

According to a further embodiment of the invention as set forth in claim 22, at least one of the enriched well structures is formed by means of a diffusion process. In the diffusion process the doping atoms intrude in the enriched well structures. A high spatial precision of the diffusion process is achieved by means of a mask, which comprises openings such that the portions, which are spatially separated from the openings, are protected from being intruded with doping atoms.

According to a further embodiment of the invention as set forth in claim 23, at least one of the enriched regions is formed by means of a diffusion process. As has already been illustrated above, the diffusion process is carried out with an appropriate mask such that a high spatial resolution of the diffusion process may be achieved.

According to a further embodiment of the invention as set forth in claim 24, the first enriched well structure is formed with a spatially non-uniform doping. In particular, the portion of the first enriched well structure, which is located in close proximity to the first enriched region, may be characterized by a different doping level compared to the portion of the first enriched well structure, which is located in close proximity to the second enriched region. This may have the effect, that the two diodes, which are formed in between the first enriched well structure and the first enriched region and in between the first enriched well structure and the second enriched region, respectively, have a different reverse breakdown voltage.

It has to be pointed out that also the breakdown voltage of the diodes formed in between the second enriched well structure and the third enriched region and/or the second enriched well structure and the first enriched semiconductor layer, respectively, may by adjusted by varying the doping level of the second enriched well structure.

According to a further embodiment of the invention as set forth in claim 25, the method further comprises the step of forming a mask in between the substrate and the first enriched semiconductor layer. This has the advantage that an effective ohmic resistance is introduced between the fourth enriched region and the diode formed between the second enriched well structure and the first enriched semiconductor layer. In case an asymmetric design with respect to the breakdown voltages of the corresponding protection circuit is used such an ohmic resistance may be used in order to distribute the overall ESD current onto the two electric paths formed in between the two conductors.

It has to be pointed out that also a mask formed in between the first enriched region and the corresponding contact elements and/or the second enriched region and the corresponding contact element, respectively, might be introduced in order to form a further ohmic resistance. Further, it has to be noted that certain embodiments of the invention have been described with reference to circuit arrangements, to an integrated electronic device and to integrated circuit elements whereas other embodiments of the invention have been described with reference to methods for manufacturing integrated circuit elements. However, a person skilled in the art will gather from the above and the following description that, unless other notified, in addition to any combination of features belonging to one category of claims also any combination between features of described in different claims is possible and considered to be is disclosed within this application.

### BRIEF DESCRIPTION OF THE DRAWINGS

The aspects defined above and further aspects of the present invention are apparent from the examples of embodiment to be described hereinafter and are explained with reference to the examples of embodiment. The invention will be described in more detail hereinafter with reference to examples of embodiment but to which the invention is not limited.

FIG. 1 shows a circuit diagram depicting a protection circuit with two electric paths each comprising a back-to-back configuration of two diodes.

FIG. 2 shows a circuit diagram depicting a protection circuit with two electric paths each comprising a back-to-back configuration of two diodes and a resistor.

FIG. 3 shows a sectional view of an integrated circuit element representing the protection circuit as depicted in FIG. 2.

FIG. 4 shows a top view of a portion of an integrated circuit element, the portion comprising two concentric formed diodes having different breakthrough voltages.

The illustration in the drawing is schematically. It is noted that in different drawings, similar or identical elements are provided with the same reference signs or with reference signs, which are different from the corresponding reference signs only within the first digit.

### DESCRIPTION OF EMBODIMENTS

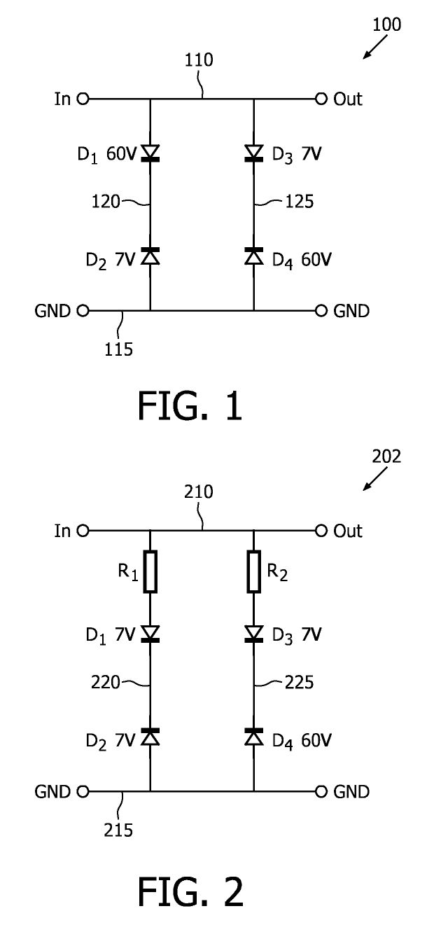

FIG. 1 shows a protection circuit 100 comprising two conductors, a first conductor 110 and a second conductor 115. The first conductor 110 comprises an input terminal In, which is adapted to be connected to a first voltage signal. The second conductor 115 is adapted to be connected to a reference voltage, which according to the embodiment described herewith is ground level GND. The first conductor 110 further comprises an output terminal Out which is connected to an input of a CMOS component (not shown). The second conductor 115 is also adapted to be connected to a ground terminal of the CMOS component.

Usually, between the terminal In and the terminal GND there may be applied a data signal. The data signal might have a high frequency such that a plurality of data bits might be transmitted from the input In to the output Out.

In between the first conductor 110 and the second conductor 115 there are formed two electric paths, a first path 120 and a second path 125, respectively. The first path 120 comprises a first diode D₁ and a second Diode D₂, which are arranged in a back-to-back configuration with respect to each other. This means, that the cathodes of both diodes D₁ and D₂ are directly connected with each other. The diode D₁ has a low capacitance and a high reverse breakdown voltage of 60V. The diode D₂ has a high capacitance and a low reverse breakdown voltage of 7V.

The second path 125 comprises a third diode D₃ and a fourth Diode D₄, which are also arranged in a back-to-back configuration with respect to each other. Thereby, the cathodes of both diodes D₃ and D₄ are directly connected with each other. The diode D₃ has a low capacitance and a high reverse breakdown voltage of 60V. The diode D₄ has a high capacitance and a low reverse breakdown voltage of 7V.

The symmetric arrangement of the four diodes D₁, D₂, D₃ and D₄ ensures, that depending on the polarity of an ESD event, which causes an effective overvoltage ESD peak in the range between 7V and 60V, the corresponding ESD current will always flow exclusively through one of the two paths 120 and 125. For instance, an effective ESD voltage peak of +50V will cause will cause the diodes D₁ and D₃ to be open and to provide for a forward voltage drop of approximately 1.0V, respectively. Therefore, a voltage of about 49V will be applied to the diodes D₂ and D₄, respectively. This voltage will cause D₂ to pass over into a breakthrough state, whereas D₄ with a reverse breakdown voltage of 60V will keep the second path 125 electrically closed. Therefore, in case of an effective +50V ESD peak no current will flow through the second path 125 whereas the whole ESD current will flow through the first path 120.

By contrast thereto, an effective −50 V ESD peak will cause D₂ and D₄ to be open whereas D₁ will be closed and D₃ will pass over into a breakthrough state. Therefore, no current will flow through the first path 125 whereas the whole ESD current will flow through the second path 120.

In case of voltage signals ranging between 0V and approximately 7V both paths 120 and 125 will be closed, such that the input signal will be transmitted from the terminal In to the terminal Out.

It has to be pointed out that the each electric path 120 and 125 comprises two diodes, which are arranged in series with respect to each other. Since two diodes D₁ and D₂ or D₃ and D₄, which are arranged within one electric path 120 or 125, have different reverse breakdown voltages, they also have different capacitance. Since further, the resultant capacitance of two diodes arranged in series is always smaller than the capacitance of the single diode having the smaller capacitance, the resultant capacitance of one path is significantly lower than the lower capacitance value of the diodes D₁ and D₂ or D₃ and D₄, respectively. Depending on the individual capacitances of the four diodes, the overall capacitance of the whole protection circuit is typically smaller than the capacitance caused by a single ESD protection diode. Therefore, the protection circuit 100 circuit is suitable also for applications wherein high frequency signals, in particular high frequency data signals, are transmitted from the input In to the output Out.

In the following there is given a brief summary of advantageous properties of the protection circuit 100:
The protection circuit 100 uses two different paths 120 and 125 for positive and negative ESD-pulses, respectively.
Due to the use of two diodes arranges in series within each path the overall resulting capacitance is reduced significantly.
The directing of the ESD-current in one direction is realized by a difference in breakdown voltages.
The protection circuit 100 may be implemented in integrated devices by means of a standard bipolar process wherein emitter-base diodes and collector-base diodes are automatically created when a transistor is built up.

It has to be pointed out that the protection circuit 100 depicted in FIG. 1 is built up integrally together with a electronic device (not shown), which is might be sensitive to ESD overvoltages. Therefore, the protection circuit 100 and the electronic device represent an integrated electronic device. The two paths ESD protection depicted in FIG. 1 has the advantage that benefiting properties like a high ESD-performance, an extremely low capacitance and a symmetric input behavior are combined. Furthermore, the integrated two paths ESD protection has all advantages, which are usually associated with a high integration of different electronic circuit arrangements within one electronic package. These are for instance the less consumed space, lower prices, lower pick and place costs, higher reliability and a better matching between neighboring circuit and/or circuit portions.

FIG. 2 shows a protection circuit 202 comprising two conductors, a first conductor 210 and a second conductor 215. The first conductor 110 comprises an input terminal In and an output terminal Out, which are equivalent to the input terminal In and the output terminal Out depicted in FIG. 1. The second conductor 215 is adapted to provide a reference voltage, which according to the embodiment depicted here is at ground level GND.

In between the first conductor 210 and the second conductor 215 there are formed two electric paths, a first path 220 and a second path 225, respectively. The first path 120 comprises a first resistor R₁, a first diode D₁ and a second Diode D₂. The second path 125 comprises a second resistor R₂, a third diode D₃ and a fourth diode D₄. The diodes D₁, D₂, D₃ and D₄ are arranged in the same manner as the diodes D₁, D₂, D₃ and D₄ shown in FIG. 1. However, apart from the additional resistors R₁ and R₂ there is a further difference between the protection circuit 100 and the protection circuit 202. In the circuit 202 the diode D₁ has a reverse breakdown voltage of 7V, only. This means that the diodes are arranged in a non-symmetric manner.

It has to be pointed out, that the resistors R₁ and R₂ shown in the circuit diagram depicted in FIG. 2 may represent both external resisters and the internal resistors of the diodes D₁, D₂, D₃ and D₄, respectively.

As has already been mentioned above, the overall resultant capacitance of the four diodes D₁, D₂, D₃ and D₄ is extremely low because of the serial connection of two diodes within each electric path 220 and 225, respectively.

The asymmetric arrangement of the four diodes D₁, D₂, D₃ and D₄ is reflected by the electric behavior of the protection circuit 202, which behavior is different for positive and negative ESD events. In the following the asymmetric behavior is illustrated for two different ESD events, which both cause a short ESD current pulse with a magnitude of about 50 A. Further, it is assumed that the ohmic resistance of R₁ is 1Ω.

A) In case of a positive ESD pulse with an ESD current of +50 A there will be a voltage drop at R₁ of 50V (=50 A/1 Ohm). Since D₁ is oriented in forward direction there will be further a forward voltage drop of about 1V at D₁. Since D₂ is oriented in backward direction and D₂ has a reverse breakdown voltage of 7V, there will be a further 7V voltage drop at D₂. By adding all voltage drops within the path 220 one obtains an overall voltage drop of 58V. This voltage is existent between the two electric paths 120 and 125. Since the reverse breakdown voltage of the diode D₄ is higher than 58V, there will be no current flowing over the second electric path 225. This means that in the ESD event described herewith the whole ESD current will flow through the left electric path 220.

As a general rule the whole ESD current will flow through the left electric path 220 when difference between the breakdown voltage U_{BD1} of the diode D₁ and U_{BD2} of the diode D₂ is big enough that the following in equation 1 is fulfilled:

$$\frac{{U}_{BD 4} - {U}_{BD 2}}{{I}_{ESD}} < {R}_{1} \qquad ( 1 )$$

B) In case of a negative ESD pulse with an ESD current of −50 A both diodes D₂ and D₄ are oriented in forward direction. As a consequence, both diodes D₂ and D₄ produce a forward voltage drop of approximately 1V. Further, it is apparent that the ESD pulse is strong enough in order to overcome the reverse breakdown voltages of both D₁ and D₃. As a consequence, the ESD current having a magnitude of 50 A will be divided according to the relation between R₁ and R₂. For instance, if one assumes that R₁ is nine times bigger than R₂, 90% of the total ESD current will flow through the second electric path 225 whereas only 10% of the total ESD current will flow through the first electric path 220. Therefore, in case of a negative ESD event the corresponding ESD current can be directed into the two paths 220 and 225 by choosing a proper relationship between the ohmic resistance of R₁ and R₂.

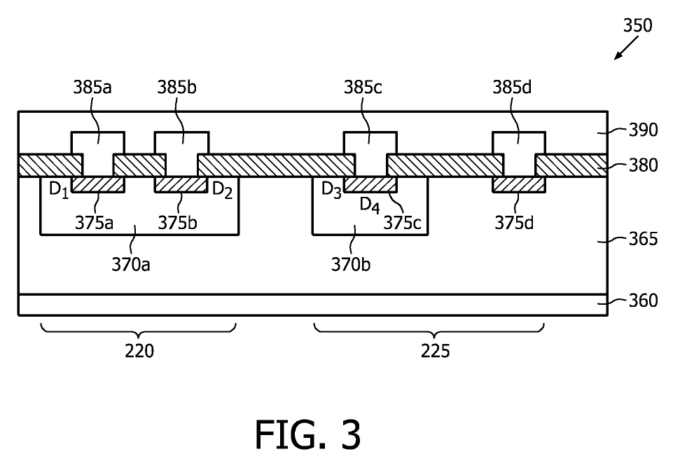

The protection circuit 202 has the advantage that by contrast to the protection circuit 100 depicted in FIG. 1 the circuit 202 may be produced by means of a semiconductor manufacturing process which comprises only four process steps wherein a mask is employed. Since process steps requiring a mask are always more time consuming and thus more expensive, the protection circuit 202 may be produced in a very efficient manner. An exemplary manufacturing process for the protection circuit 202 will be explained in the following with reference to FIG. 3.

FIG. 3 shows a sectional view of an integrated circuit element 350 representing the protection circuit 202. The circuit element 350 is formed on a substrate 360, which according to the embodiment described herewith is a low ohmic p++ enriched substrate. On the substrate 360 there is provided a p− enriched layer 365, which preferably is formed by means of an epitaxial growth procedure.

In the p− enriched layer 365 there are provided two n enriched well structures, a first n enriched well structure 370a and a second n enriched well structures 370b. These well structures 370a and 370b are formed within of a first mask step preferably be means of a so-called n well diffusion. The interface between the p− enriched layer 365 and the second n enriched well structures 370b represents a p-n-junction, which according to the embodiment described herewith represents the fourth diode D₄ depicted in FIG. 2.

In the first n enriched well structure 370a there are provided two p+ enriched regions, a first p+ enriched region 375a and a second p+ enriched region 375b, respectively. Further, in the second n enriched well structure 370b there is provided a third p+ enriched region 375c. Furthermore, in the p− enriched layer 365 there is provided a fourth p+ enriched region 375d. The p+ enriched regions 375a, 375b, 375c and 375d are formed within of a second mask step preferably be means of shallow p+ diffusion process. Each interface between the first n enriched well structure 370a and the two p+ enriched regions 375a and 375b, respectively, and the second n enriched well structure 370b and the third p+ enriched region 375c forms a p-n-junction. These three p-n-junctions represent the diodes D₁, D₂ and D₃, respectively, which are shown in FIG. 2.

On the surface defined by top surface portions of the p− enriched layer 365, the first n enriched well structure 370a, the second n enriched well structures 370b and the p+ enriched regions 375a, 375b, 375c and 375d there is formed a first passivation layer 380. According to the embodiment described here the first passivation layer 380 is made of SiO₂. However, also other isolating materials may be used in order to form the first passivation layer 380.

Within the first passivation layer 380 there are formed four openings which are located above the four p+ enriched regions 375a, 375b, 375c and 375d. In each of the openings there is accommodated a metallic contact element such that the integrated circuit element 350 comprises a first metallic contact element 385a, a second metallic contact element 385b, a third metallic contact element 385c and a fourth metallic contact element 385d. The formation of the openings as well as the formation of the four metallic contact elements 385a, 385b, 385c and 385d are preferably carried out by means of the same mask which has been used for the second mask step. Therefore, no additional mask step is needed in order to built up the four metallic contact elements 385a, 385b, 385c and 385d, respectively.

Since there is no oxidic material in between the four p+ enriched regions 375a, 375b, 375c and 375d and the four metallic contact elements 385a, 385b, 385c and 385d, respectively, there is provided a reliable electrical contact between each of the four p+ enriched regions 375a, 375b, 375c and 375d and the corresponding metallic contact element 385a, 385b, 385c and 385d, respectively.

As can be seen from the sectional view shown in FIG. 3, the upper portion of the metallic contact elements 385a, 385b, 385c and 385d is widened compared to the corresponding lower portions of the metallic contact elements 385a, 385b, 385c and 385d, respectively. The shape of the metallic contact elements 385a, 385b, 385c and 385d reflects, that the metallic contact elements 385a, 385b, 385c and 385d provide an electric contact to conductor paths, which are coated by the second protection layer 390. Therefore, the upper parts of the metallic contact elements 385a, 385b, 385c and 385d represent sectional views of such conductor paths, which extent perpendicular to the drawing plane used for the sectional view of the circuit element 350. These conductor paths are structured within a third mask step.

In order to further protect the integrated circuit element 350, above the first passivation layer 380 and the four metallic contact elements 385a, 385b, 385c and 385d including the conductor paths there is provided a second passivation layer 390. The second passivation layer is preferably made of Si₃N₄.

In order to contact the whole integrated circuit element 350 there are provided openings (not shown) in the second passivation layer 390. Typically, these openings are filled with solder balls, which are used for permanently contacting the circuit element 350 with contact pads or lands formed on a substrate (e.g. a printed circuit board) or on contact pads formed on other semiconductor devices. A permanent contact between the contact pads and the integrated circuit element is usually established with a solder or a gluing process. The openings within the second passivation layer 390 are formed by means of a fourth mask step.

As can be seen from the description given above, the integrated circuit element 350 may be produced by means of a semiconductor manufacturing process, which altogether necessitates four mask steps only. Therefore, the asymmetric circuit arrangement 202 shown in FIG. 2 can be realized in a very effective and inexpensive way.

In this context it is noted that the circuit element 350 shown in FIG. 3 might be modified by applying a further mask step wherein the area of the interface between the substrate 360 and the p− enriched layer 365 is reduced. Thereby, the value of the resistor R₂ shown in FIG. 2 is increased. This means that by establishing such a further mask step the exact resistance of R₂ may be adjusted.

A further modification to the production of the circuit element 350 may be the carried out by a further mask step wherein two different low breakdown voltages of the diodes D₁ and D₃ can be generated. Thereby, a shallow n diffusion is introduced in between the first n enriched well structure 370a and the p− enriched layer 365. Such a spatially located n diffusion causes the doping level of the first n enriched well structure 370a as to be different from the doping level of the second n enriched well structure 370b. Thereby, different reverse breakdown voltages of the diodes D₁ and D₃ can be generated.

It has to be pointed out that a decrease of the doping level within an n enriched well structure causes an increase of the corresponding reverse breakdown voltage of a diode formed at the interface between the n enriched well structure and the corresponding p+ enriched region. This matter of fact provides the possibility that also a difference between the breakdown voltages of D₁ and D₂ may be generated by a further spatially non-uniform n diffusion within the first enriched well structure 370a. For instance, the right portion of the first enriched well structure 370a might comprise a higher n doping level than the left portion of the first enriched well structure 370a. This would cause the reverse breakdown voltage of the diode D₂ to be lower than the reverse breakdown voltage of the diode D₁. Therefore, by properly adjusting both the doping level of the second n enriched well structure 370b and the doping level of the spatially inhomogeneous first enriched well structure 370a one can manufacture the protection circuit 202 having an asymmetric diode arrangement in an easy and very reliable way.

The electric behavior of the circuit element 350 in case of a negative ESD pulse is improved if the diode with the higher breakdown voltage is arranged in the first path 220 of the circuit arrangement 202. This means that the diode with the higher breakdown voltage is the diode D₁ shown in FIG. 2. The portion of the ESD current flowing through the first path 220 under negative ESD-stress is then reduced. The formula for calculating this part of the ESD current is given by the following equation:

$$\frac{{I}_{1}}{{I}_{ESD}} = \frac{{R}_{2} {I}_{ESD} - ( {U}_{BD 1} - {U}_{BD 3} )}{{I}_{ESD} ( {R}_{1} + {R}_{2} )} \qquad ( 2 )$$

Thereby, I₁ is the current flowing through the first electric path 220. I_{ESD} is the whole ESD current, which is induced by the ESD event comprising a negative polarity. R₁ and R₂ are the ohmic resistances of the resistors R₁ and R₂ depicted in FIG. 2. U_{BD1} is the reverse breakdown voltage of the diode D₁ and U_{BD2} is the reverse breakdown voltage of the diode D₂, respectively.

It has to be pointed out that the same electrical behavior of the circuit element 350 can be realized when the doping types of the semiconductor materials are interchanged. This means, that in all regions with a p-type doping an n-type doping is provided and in all regions with an n-type doping a p-type doping with the same doping level is provided.

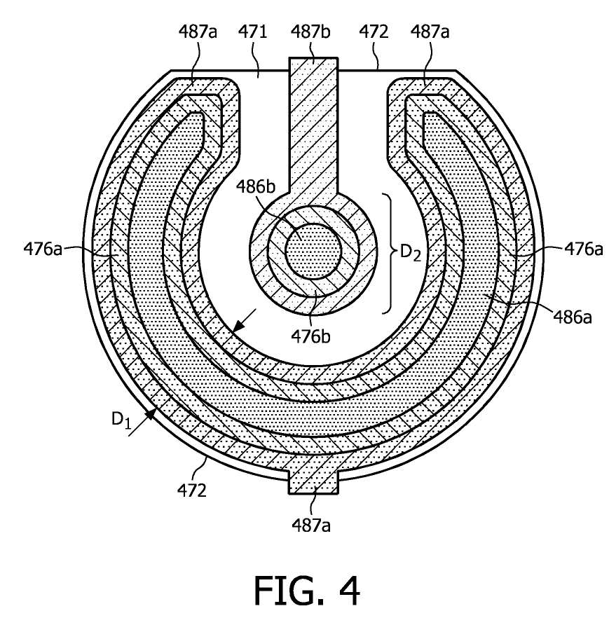

FIG. 4 shows a top view of an n enriched well structure 471, wherein diodes D₁ and D₂ having different reverse breakdown voltages are formed in an elegant manner. Reference numeral 472 denotes the edge of the well structure 471.

The first diode D₁ is formed by the interface between a first p+ enriched region 476a and the n enriched well structure 471. Die diode D₁ is contacted by a lower portion 486a of a first metallic contact, which is formed on the first p+ enriched region 476a. An upper portion 487a of the first metallic contact is formed on a first passivation layer (not shown in FIG. 4).

The second diode D₂ is formed by the interface between a second p+ enriched region 476b and the n enriched well structure 471. Die diode D₂ is contacted by a lower portion 486b of a second metallic contact, which is formed on the second p+ enriched region 476b. An upper portion 487b of the second metallic contact is formed on the first passivation layer (not shown in FIG. 4).

As can be seen from FIG. 4, the diode D₁ is formed around the second diode D₂ in a circular arc wise manner. Thereby, the diode D₂ has the shape of a section of a concentric annulus with respect to the central second diode D₂.

It should be noted that the term “comprising” does not exclude other elements or steps and the “a” or “an” does not exclude a plurality. Also elements described in association with different embodiments may be combined. It should also be noted that reference signs in the claims should not be construed as limiting the scope of the claims.

In order to recapitulate the above described embodiments of the present invention one can state:

It is described an Electro Static Discharge protection, wherein diodes are arranged on two electric paths both extending in between two conductors which are connected with input terminals of an ESD sensitive electronic component. Each path comprises two diodes arranged in series and with opposite polarity with respect to each other. At least one of the totally four diodes comprises a different reverse breakdown voltage. The protection circuit is formed integrally with the ESD sensitive electronic component. Due to the serial connection of two diodes in each path the corresponding ESD protection circuit comprises an extremely low capacitance.

According to a first embodiment the two paths concept combines two diodes of low capacitance and high breakdown voltage with two diodes of high ESD performance and high capacitance. A first path will protect the right path and the connected ICs from positive ESD-pulses and vice versa for negative ESD pulses.

According to a second embodiment only one diode with a high reverse breakdown voltage is provided in connection to ground. In case of a negative ESD pulse the protection of a first path is realized by tuning the relation of internal resistances of the two paths.

The described integrated ESD protection can be used for electronic equipment or integrated circuits especially for all handheld equipment like cellular phones, media players, et cetera, where space is an important factor. The low capacitance of the two path integrated ESD protection device makes it suitable for fast applications like USB 2.0.

### LIST OF REFERENCE SIGNS

100 protection circuit
110 first conductor
115 second conductor
120 first electric path
125 second electric path
D₁ diode
D₂ diode
D₃ diode
D₄ diode
In input
Out output
GND ground
202 protection circuit
210 first conductor
215 second conductor
220 first electric path
225 second electric path
D₁ diode
D₂ diode
D₃ diode
D₄ diode
R1 resistance
R2 resistance
In input
Out output
GND ground
350 integrated circuit element
360 p++ enriched substrate
365 p− enriched epitaxial grown layer
370a first n enriched well structure
370b second n enriched well structure
375a first p+ enriched region
375b second p+ enriched region
375c third p+ enriched region
375d fourth p+ enriched region
380 first passivation layer (SiO₂)
385a first metallic contact element
385b second metallic contact element
385c third metallic contact element
385d fourth metallic contact element
390 second passivation layer (Si₃N₄)
D₁ diode
D₂ diode
D₃ diode
D₄ diode
471 n enriched well structure
472 edge of n enriched well structure
476a first p+ enriched region
476b second p+ enriched region
486a lower portion of a first metallic contact (formed on the first p+ enriched region)
486b lower portion of a second metallic contact (formed on the second p+ enriched region)
487a upper portion of the first metallic contact (formed on the first passivation layer)
487b upper portion of the second metallic contact(formed on the first passivation layer)
D₁ diode
D₂ diode

1. Circuit arrangement for protecting electronic components from being damaged due to voltage overloads, in particular for protecting integrated semiconductor devices from being damaged due to electrostatic discharge currents, the circuit arrangement comprising
a first conductor, adapted to be connected to a first voltage level,
a second conductor, adapted the be connected to a second voltage level,
a first electric path interconnecting the first conductor and the second conductor,
a second electric path interconnecting the first conductor and the second conductor,
a first diode and a second diode arranged within the first electric path in series and with opposite polarity with respect to each other, wherein the first diode has a first reverse breakdown voltage and the second diode has a second reverse breakdown voltage,
a third diode and a fourth diode arranged within the second electric path in series and with opposite polarity with respect to each other, wherein the third diode has a third reverse breakdown voltage and the fourth diode has a fourth reverse breakdown voltage which is different from the third reverse breakdown voltage, wherein the circuit arrangement is formed integrally with at least one further electronic component which is connected to the first conductor and to the second conductor respectively.

2. Circuit arrangement according to claim 1, wherein the circuit arrangement and the further electronic component are formed within one semiconductor crystal.

3. Circuit arrangement according to claim 1, wherein the second voltage level is at ground level.

4. Circuit arrangement according to claim 1, wherein the first diode and the third diode are arranged in the same polarity with respect to the first conductor and the second diode and the fourth diode are arranged in the same polarity with respect to the second conductor.

5. Circuit arrangement according to claim 1, wherein the first reverse breakdown voltage is the same as the fourth reverse breakdown voltage and the second reverse breakdown voltage is the same as the third reverse breakdown voltage.

6. Circuit arrangement according to claim 5, wherein the first reverse breakdown voltage is between 30 volts and 100 volts, preferably between 50 volts and 80 volts, and the second reverse breakdown voltage is between 3 volts and 20 volts, preferably between 5 volts and 15 volts.

7. Circuit arrangement according to claim 1, wherein the first, the second and the third reverse breakdown voltages have the same value.

8. Circuit arrangement according to claim 7, further comprising a first resistor arranged in the first electric path and a second resistor arranged in the second electric path.

9. Circuit arrangement according to claim 8, wherein the first resistor is arranged in series with respect to the first diode and with respect to the second diode, respectively, and the second resistor is arranged in series with respect to the third diode and with respect to the fourth diode, respectively.

10. Circuit arrangement according to claim 7, wherein the first reverse breakdown voltage is between 3 volts and 20 volts, preferably between 5 volts and 15 volts, and the fourth reverse breakdown voltage is between 30 volts and 100 volts, preferably between 50 volts and 80 volts.

11. Integrated electronic device, comprising an electronic component and a circuit arrangement according to claim 1.

12. An integrated circuit element for protecting electronic components from being damaged due to voltage overloads, in particular for protecting integrated semiconductor devices from being damaged due to unwanted electrostatic discharge currents, the integrated circuit element comprising
a first enriched semiconductor layer,
a first enriched well structure and a second enriched well structure, which are both formed in the first enriched semiconductor layer,
a first enriched region and a second enriched region, which are both formed in the first enriched well structure,
a third enriched region formed in the second enriched well structure,
a fourth enriched region formed in the first enriched semiconductor layer,
a first passivation layer formed on a common surface defined by top surfaces portions of the first enriched semiconductor layers, by the first and second enriched well structures and by the first, the second, the third and the fourth enriched regions, wherein the first passivation layer comprises four through holes for contacting the enriched regions,
a first contact element accommodated in a first through hole for contacting the first enriched region,
a second contact element accommodated in a second through hole for contacting the second enriched region,
a third contact element accommodated in a third through hole for contacting the third enriched region, and
a fourth contact element accommodated in a fourth through hole for contacting the fourth enriched region.

13. The integrated circuit element according to claim 12, further comprising
a substrate providing a basis for the first enriched semiconductor layer.

14. The integrated circuit element according to claim 13, wherein the substrate is made from a low ohmic enriched semiconductor material.

15. The integrated circuit element according to claim 12, further comprising a second passivation layer formed on the contact elements and on portions of the first passivation layer.

16. The integrated circuit element according to claim 15, wherein the second passivation layer comprises openings for electrically connecting the contact elements.

17. The integrated circuit element according to claim 12, wherein the first enriched region is formed around the second enriched region in an arc wise manner, preferably in a circular arc wise manner.

18. Method for manufacturing an integrated circuit element for protecting electronic components from being damaged due to voltage overloads, in particular for protecting integrated semiconductor devices from being damaged due to electrostatic discharge currents, the method comprising the steps of:
forming a first enriched semiconductor layer on a substrate,
forming a first enriched well structure and a second enriched well structure in the first layer,
forming a first enriched region and a second enriched region in the first well structure,
forming a third enriched region in the second enriched well structure,
forming a fourth enriched region in the first enriched semiconductor layer,
forming a first passivation layer on a surface defined by top surface portions of the first enriched semiconductor layer, the first and second enriched well structures and the first, the second, the third and the fourth enriched regions,
forming four through holes in the first passivation layer,
forming four contact elements each being accommodated within one through hole such that each of the four enriched regions is contacted with one of the four contact elements.

19. The method according to claim 18, further comprising the step of forming a second passivation layer on the contact elements, and on portions of the first passivation layer.

20. The method according to claim 19, further comprising the steps of forming openings in the second passivation layer and electrically connecting the contact elements via these openings.

21. The method according to claim 18, wherein the first enriched semiconductor layer is formed on the substrate by means of an epitaxial growth procedure.

22. The method according to claim 18, wherein at least one of the enriched well structures is formed by means of a diffusion process.

23. The method according to claim 18, wherein at least one of the enriched regions is formed by means of a diffusion process.

24. The method according to claim 18, wherein the first enriched well structure is formed with a spatially non-uniform doping.

25. The method according to claim 18, further comprising the step of forming a mask in between the substrate and the first enriched semiconductor layer.
